(19) United States
(12) Patent Application Publication
(10) Pub. No.: US 2026/0051348 A1
(43) Pub. Date: Feb. 19, 2026

(54) SENSE AMPLIFIER CIRCUIT, MEMORY DEVICE INCLUDING THE SAME AND SENSING METHOD OF MEMORY DEVICE

(71) Applicant: Samsung Electronics Co., Ltd., Suwon-si (KR)

(72) Inventors: Changyoung Lee, Suwon-si (KR); Young Seok Park, Suwon-si (KR); Hyun-Chul Yoon, Suwon-si (KR); Younghun Seo, Suwon-si (KR)

(21) Appl. No.: 19/015,959

(22) Filed: Jan. 10, 2025

(30) Foreign Application Priority Data
Aug. 14, 2024 (KR) 10-2024-0108935

(51) Int. Cl. G11C 11/4091; G11C 11/4094

(52) U.S. Cl. CPC G11C 11/4091; G11C 11/4094

(57) ABSTRACT

A sense amplifier circuit may include a first bit line, a bit line transistor electrically connected between the first bit line and a first node, a first control transistor electrically connected between the first node and a second node, a first inverter including an input terminal electrically connected to the second node, a second inverter electrically connected to an output node, and a precharge circuit electrically connected to the second node and configured to transfer a first voltage to the second node during a first time period and to transfer a second voltage greater than the first voltage to the second node during a second time period.

### CROSS-REFERENCE TO RELATED APPLICATIONS

This application claims priority to and the benefit of Korean Patent Application No. 10-2024-0108935 filed in the Korean Intellectual Property Office on Aug. 14, 2024, the entire contents of which are incorporated herein by reference.

### BACKGROUND OF THE INVENTION

The present disclosure relates to a sense amplifier circuit, a memory device including the same, and a sensing method of the memory device.

During a read operation or a refresh operation of a memory device, a sense amplifier may sense data of a memory cell by detecting the voltage difference between a bit line and a complementary bit line. As memory devices become more highly integrated, memory cell sizes shrink and bit line loads increase, and thus it may be difficult to maintain the margin of the voltage difference. If the voltage difference margin is not maintained, data sensing of the memory cell may fail.

### SUMMARY OF THE INVENTION

Example embodiments provide a sense amplifier circuit for amplifying a small voltage difference between a bit line and a complementary bit line, a memory device including the same, and a sensing method of the memory device.

Example embodiments provide a sense amplifier circuit operating at low power, a memory device including the same, and a sensing method of the memory device.

According to some embodiments of the present disclosure, a sense amplifier circuit may include a first bit line, a bit line transistor electrically connected between the first bit line and a first node, a first control transistor electrically connected between the first node and a second node, a first inverter including an input terminal electrically connected to the second node, a second inverter electrically connected to an output node, and a precharge circuit electrically connected to the second node and configured to transfer a first voltage to the second node during a first time period and to transfer a second voltage greater than the first voltage to the second node during a second time period.

According to some embodiments of the present disclosure, a sense amplifier circuit may include a memory cell, a bit line electrically connected to the memory cell, a first node, a second node, a bit line transistor electrically connected between the bit line and the first node, a first control transistor electrically connected between the first node and the second node, a first inverter including an input terminal electrically connected to the second node, a second inverter including an output terminal electrically connected to an output node, and a first precharge transistor electrically connected between the second node and the output node, wherein the sense amplifier circuit is configured to: during a first time period, transfer a first voltage to the bit line, the first node, and the second node while the first control transistor is turned on, during a second time period after the first time period, transfer a second voltage greater than the first voltage to the second node while the first precharge transistor is turned off, during a third time period after the second time period, perform a charge sharing operation between a capacitance component of the bit line and the memory cell, wherein the bit line transistor is configured to turn off during the third time period, and during a fourth time period after the third time period, transfer a charge from the bit line to the second node, wherein the bit line transistor is configured to turn on during the fourth time period, wherein during a fifth time period after the fourth time period, a first voltage line and a second voltage line electrically connected to each of the first inverter and the second inverter are configured to turn on, and wherein during a sixth time period after the fifth time period, the first control transistor is configured to be on and the first precharge transistor is configured to turn on.

According to some embodiments of the present disclosure, a sensing method of a memory device may include precharging a bit line and a first node electrically connected to the bit line with a first voltage, storing offset information of a transistor electrically connected between the first node and a second node, precharging the second node with a second voltage greater than the first voltage and sharing a charge between a memory cell and the bit line, transferring the charge from the bit line to the second node, and sensing data of the memory cell based on a voltage at the second node.

### BRIEF DESCRIPTION OF THE DRAWINGS

FIG. 1 is a block diagram illustrating a memory device according to some embodiments.

FIG. 2 is a diagram illustrating a memory cell array and a sense amplifier in a memory device according to some embodiments.

FIG. 3 is a circuit diagram illustrating the connection of a memory cell and a sense amplifier circuit in a memory device according to some embodiments.

FIG. 4 is a perspective view illustrating the memory device of FIG. 1 according to some embodiments.

FIG. 5 is a circuit diagram illustrating the memory cell array of FIG. 1 according to some embodiments.

FIG. 6 is a circuit diagram illustrating a sense amplifier circuit according to some embodiments.

FIG. 7 is a diagram illustrating the operation timing of a sense amplifier circuit according to some embodiments.

FIG. 8 is a circuit diagram illustrating a sense amplifier circuit that performs a precharge operation according to some embodiments.

FIG. 9 is a circuit diagram illustrating a sense amplifier circuit that performs an offset compensation operation according to some embodiments.

FIG. 10 is a circuit diagram illustrating a sense amplifier circuit that performs a charge sharing operation according to some embodiments.

FIG. 11 is a circuit diagram illustrating a sense amplifier circuit that performs a charge transfer operation according to some embodiments.

FIG. 12 is a graph illustrating the offset variation of the sense amplifier circuit, the variation of the charge sharing period, and the variation of the charge transfer period according to some embodiments.

FIG. 13 is a circuit diagram illustrating a sense amplifier circuit that performs a sensing operation according to some embodiments.

FIG. 14 is a circuit diagram illustrating a sense amplifier circuit that performs a restoration operation according to some embodiments.

FIG. 15 is a diagram illustrating the operation timing of a sense amplifier circuit according to some embodiments.

FIG. 16 is a graph illustrating the amount of current generated in a sense amplifier circuit according to some embodiments.

FIG. 17 is a diagram illustrating the operation timing of a sense amplifier circuit according to some further embodiments.

FIG. 18 is a circuit diagram illustrating a third precharge transistor turned off during an offset compensation operation process according to some further embodiments.

FIG. 19 is a diagram illustrating the operation timing of a sense amplifier circuit according to some further embodiments.

FIG. 20 is a block diagram illustrating a computer device according to some embodiments.

### DETAILED DESCRIPTION

Hereinafter, example embodiments of the present disclosure will be described in detail with reference to the accompanying drawings so that those skilled in the art may easily implement the present disclosure. However, the present disclosure may be implemented in various different forms and is not limited to the embodiments described herein.

And, in order to clearly explain the present disclosure in the drawings, parts that are not related to the explanation may be omitted, and similar parts are given similar drawing reference numerals throughout the specification.

Additionally, expressions written in the singular may be interpreted as singular or plural, unless explicit expressions such as “one” or “singular” are used. Terms that include ordinal numbers, such as first, second, etc., may be used to describe various components, but the components are not limited by these terms. Rather, these terms are only used to distinguish one element from another. For example, a first element could be termed a second element, and, similarly, a second element could be termed a first element, without departing from the scope of the present disclosure.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. As used herein, the term “and/or” includes any and all combinations of one or more of the associated listed items.

Hereinafter, example embodiments of the present disclosure will be described in more detail. These embodiments are intended only to illustrate the present disclosure, and the scope of the present disclosure is not limited by these embodiments.

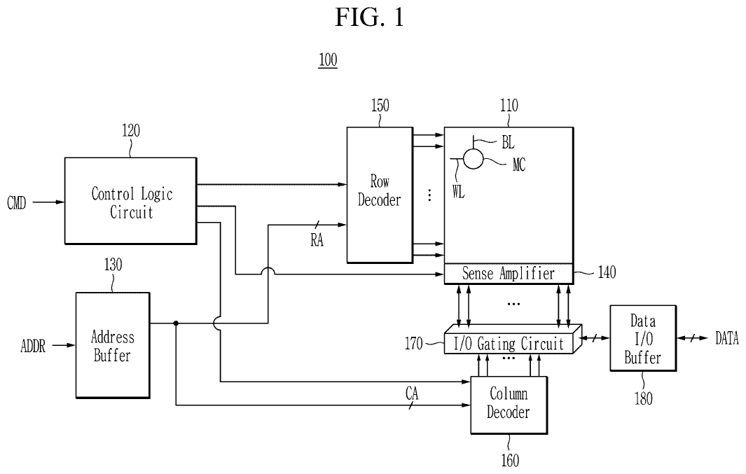

FIG. 1 is a block diagram illustrating a memory device according to some embodiments.

Referring to FIG. 1, a memory device 100 may include a memory cell array 110, a control logic circuit 120, an address buffer 130, a sense amplifier 140, a row decoder 150, a column decoder 160, an input/output (I/O) gating circuit 170, and a data I/O buffer 180. In some embodiments, the memory device 100 may be a dynamic random-access memory DRAM, but is not limited thereto.

The memory cell array 110 may include a plurality of rows, a plurality of columns, and a plurality of memory cells MC arranged at intersections of the plurality of rows and the plurality of columns. A plurality of rows may be defined by a plurality of word lines WL, and a plurality of columns may be defined by a plurality of bit lines BL.

The control logic circuit 120 controls the operation of the memory device 100. For example, the control logic circuit 120 may generate a control signal so that the memory device 100 performs a read operation, a write operation, or a refresh operation. In some embodiments, the control logic circuit 120 may generate a control signal by decoding a command CMD received from a memory controller (not shown). In some embodiments, the control logic circuit 120 may transmit a control signal to the sense amplifier 140, the row decoder 150, and the column decoder 160.

The address buffer 130 may receive an address ADDR provided from the memory controller. The address ADDR may include a row address RA indicating a row of the memory cell array 110 and a column address CA indicating a column of the memory cell array 110. The row address RA may be provided to the row decoder 150, and the column address CA may be provided to the column decoder 160.

The row decoder 150 may select a row to be activated among a plurality of rows of the memory cell array 110 based on the row address RA. To this end, the row decoder 150 may apply a driving voltage to the word line WL corresponding to the row to be activated.

The column decoder 160 may select a column to be activated among a plurality of columns of the memory cell array 110 based on the column address CA. To this end, the column decoder 160 may activate the sense amplifier 140 corresponding to the column address CA through the input/output (I/O) gating circuit 170. The sense amplifier 140 may be connected to the bit line BL of the memory cell array 110. The sense amplifier 140 may sense a voltage of the bit line BL and output the sensed voltage. In some embodiments, the input/output (I/O) gating circuit 170 gates input/output data and may include a data latch for storing data read from the memory cell array 110 and a write driver for writing data to the memory cell array 110. A data read from the memory cell array 110 may be sensed by the sense amplifier 140 and stored in the input/output (I/O) gating circuit 170 (e.g., a data latch).

In some embodiments, data read from the memory cell array 110 (e.g., data stored in a data latch) may be provided to the memory controller via a data I/O buffer 180. Data to be written into the memory cell array 110 is provided from the memory controller to the data I/O buffer 180 and the data provided to the data I/O buffer 180 can be provided to the input/output (I/O) gating circuit 170.

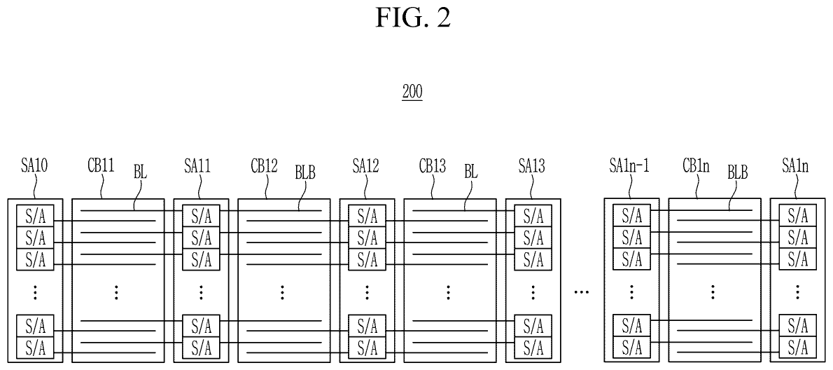

FIG. 2 is a diagram illustrating a memory cell array and a sense amplifier in a memory device according to some embodiments.

Referring to FIG. 2, the memory cell array 200 may include a plurality of memory cell blocks (CB11, CB12, CB13, . . . CB1n) and a plurality of sense amplifier blocks (SA10, SA11, SA12, SA13, . . . SA1n−1, SA1n), where n is a positive integer. Each sense amplifier block SA1i corresponds to two adjacent memory cell blocks (CB1i, CB1i+1) among a plurality of memory cell blocks (CB11−CB1n), and may be connected to two adjacent memory cell blocks (CB1i, CB1i+1), where i is an integer from 1 to (n−1).

Each memory cell block CB1i may include a plurality of bit lines BLs extending in a predetermined direction (e.g., in the column direction). A plurality of memory cells may be connected to each bit line BL. A memory cell block CB1i may further include a plurality of word lines extending in a different direction (e.g., in the row direction). A plurality of memory cells connected to each bit line BL may be respectively connected to a plurality of word lines. In some embodiments, as illustrated in FIG. 2, some memory cell blocks among a plurality of memory cell blocks CB11 to CB1n may include a complementary bit line BLB as a bit line. In this case, memory cell blocks in which bit lines BLs are formed and memory cell blocks in which complementary bit lines BLBs are formed are arranged alternately, and the bit lines BLs and the complementary bit lines BLBs may form a complementary bit line pair.

The sense amplifier block SA1i may be connected to some bit lines BL of one memory cell block CB1i and some complementary bit lines BLB of another memory cell block CB1i+1. In some embodiments, the sense amplifier block SA1i may be connected to an odd bit line BL of the memory cell block CB1i and an odd complementary bit line BLB of the memory cell block CB1i+1. In this case, the even bit line BL of the memory cell block CB1i may be connected to another sense amplifier block SA1i−1, and the even complementary bit line BLB of the memory cell block CB1i+1 may be connected to another sense amplifier block SA1i+1. In some other embodiments, the sense amplifier block SA1i may be connected to an even bit line BL of the memory cell block CB1i and an even complementary bit line BLB of the memory cell block CB1i+1.

In some embodiments, a sense amplifier block SA10 located at one end may be connected to a bit line BL of one memory cell CB11, and a sense amplifier block SA1n located at the other end may be connected to a complementary bit line BLB of one memory cell CB1n.

The sense amplifier block SA1i may include a plurality of sense amplifiers S/A. A plurality of sense amplifiers S/A may correspond to some bit lines BL of the memory cell block CB1i, and may correspond to some complementary bit lines BLB of other memory cell blocks CB1i+1, respectively. Each sense amplifier S/A may be connected to a corresponding bit line BL among some bit lines (e.g., odd bit lines) BL of a memory cell block CB1i and a corresponding complementary bit line BLB among some complementary bit lines (e.g., odd complementary bit lines) BLB of another memory cell block CB1i+1.

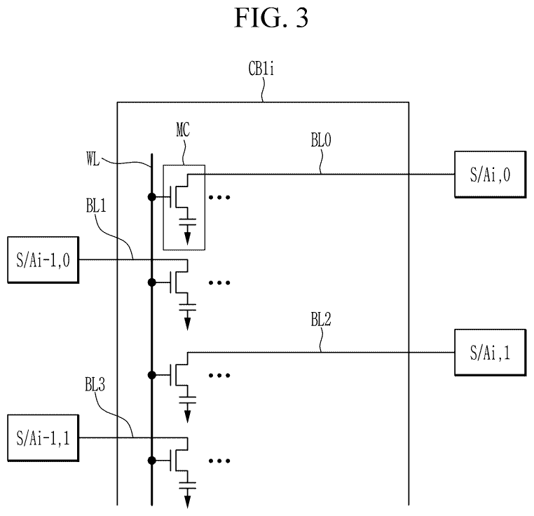

FIG. 3 is a circuit diagram illustrating the connection of a memory cell and a sense amplifier circuit in a memory device according to some embodiments.

As shown in FIG. 3, in the cell array block CB1i, the bit lines (BL0, BL2) may be respectively connected to the sense amplifiers (S/Ai,0, S/Ai,1) of the sense amplifier block SA1i, and the bit lines (BL1, BL3) may be respectively connected to the sense amplifiers (S/Ai-1,0, S/Ai-1,1) of the sense amplifier block SA1i-1. In FIG. 3, one word line WL and a memory cell MC connected to the word line WL are illustrated for convenience of description. Additionally, in FIG. 3, although each memory cell MC is illustrated as including a transistor and a capacitor, the structure of the memory cell MC is not limited thereto.

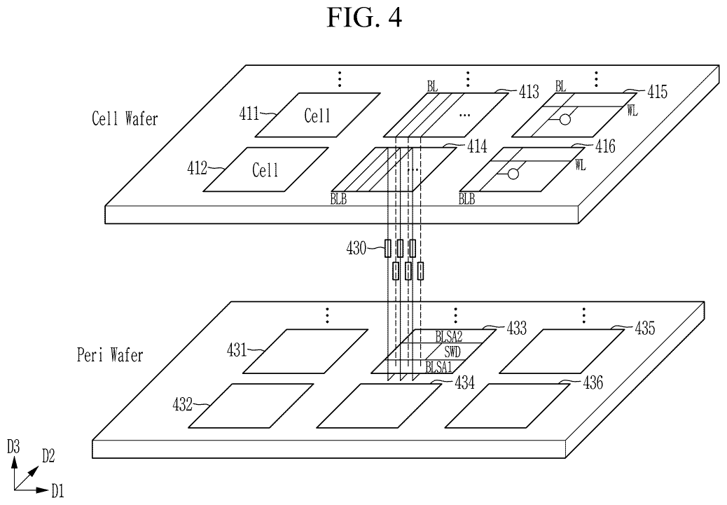

FIG. 4 is a perspective view illustrating the memory device of FIG. 1 according to some embodiments.

Referring to FIGS. 1 to 4, a memory device (100 in FIG. 1) may include a cell wafer, a peri wafer, and a bonding pad 430 that electrically connects the cell wafer and the peri wafer. As used herein, the peri wafer may also be referred to as a peripheral wafer.

A cell wafer may include a plurality of memory cell regions 411 to 416. Among the plurality of memory cell regions 411 to 416, some of the memory cell regions 411, 413, and 415 may include a plurality of word lines WL, a plurality of bit lines BL, and a plurality of memory cells MC arranged at intersections of the plurality of word lines WL and the plurality of bit lines BL. Among the plurality of memory cell regions 411 to 416, the remaining memory cell regions 412, 414, and 416, excluding some of the memory cell regions 411, 413, and 415, may include a plurality of word lines WL, a plurality of complementary bit lines BLB, and a plurality of memory cells MC arranged at intersections of the plurality of word lines WL and the plurality of complementary bit lines BLB. The cell wafer may be arranged to overlap the peri wafer along the third axis D3 direction. As used herein, “an element A overlaps an element B in a direction X” (or similar language) means that there is at least one straight line that extends in the direction X and intersects both the elements A and B.

The peri wafer may include a plurality of peri regions 431 to 436. Each of the plurality of peri regions 431 to 436 may include a sub word line driver region SWD arranged along the second axis D2 direction and bit line sense amplifier regions BLSA1, BLSA2 arranged along the first axis D1 direction. A plurality of sub word line drivers may be placed in the sub word line driver region SWD. A plurality of sub word line drivers may activate specific word lines among a plurality of word lines. A plurality of bit line sense amplifiers may be arranged in the bit line sense amplifier regions BLSA1, BLSA2. A plurality of bit line sense amplifiers may determine the state of memory cells connected to a plurality of bit lines BLs or a plurality of complementary bit lines BLBs.

The bit line sense amplifier regions BLSA1, BLSA2 may be electrically connected to some of the plurality of memory cell regions 411 to 416 through bonding pads 430. At this time, the bit line sense amplifier regions BLSA1, BLSA2 may be connected to the bit lines BL and complementary bit lines BLB included in a plurality of memory cell regions 411 to 416.

For example, the bit line sense amplifier regions BLSA1, BLSA2 of the first peri region 433 may be electrically connected to the bit line BL of the third memory cell region 413 and the complementary bit line BLB of the fourth memory cell region 414 adjacent to each other in the third axis D3 direction.

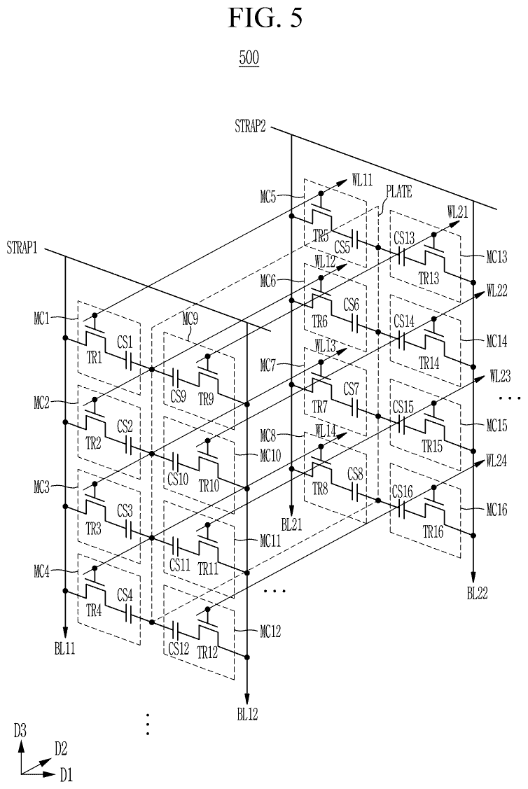

FIG. 5 is a circuit diagram illustrating the memory cell array of FIG. 1 according to some embodiments.

Referring to FIG. 5, a memory cell array 500 may include a plurality of memory cells MC1 to MC16 stacked in a third axis D3 direction. A plurality of memory cells MC1 to MC16 may be connected to a plurality of bit lines BL11, BL12, BL21, and BL22 disposed along the third axis D3 direction. For example, the first to fourth memory cells MC1 to MC4 may be connected to the first bit line BL11, and the fifth to eighth memory cells MC5 to MC8 may be connected to the second bit line BL21. In addition, the ninth to twelfth memory cells MC9 to MC12 may be connected to the third bit line BL12, and the thirteenth to sixteenth memory cells MC13 to MC16 may be connected to the fourth bit line BL22.

The first bit line BL11 and the third bit line BL12 may be connected to the first strap STRAP1 disposed along the direction of the first axis D1. Also, the second bit line BL21 and the fourth bit line BL22 may be connected to a second strap STRAP2 disposed along the first axis D1 direction. The number of bit lines connected to the first strap STRAP1 and the second strap STRAP2 and the number of memory cells connected to the plurality of bit lines are only examples and are not limited to the number shown in FIG. 5.

A plurality of word lines WL11, WL12, WL13, WL14, WL21, WL22, WL23, and W24 are disposed along the second axis D2 direction and may apply a voltage to gates of the transistors TR1 to TR16 included in a plurality of memory cells MC1 to MC16.

The word lines WL11, WL12, WL13, and WL14 may be connected to the transistors TR1 to TR4 connected to the first bit line BL11 and the transistors TR5 to TR8 connected to the second bit line BL21. For example, the first word line WL11 may be connected to the gate of the first transistor TR1 and the gate of the fifth transistor TR5, and the second word line WL12 may be connected to the gate of the second transistor TR2 and the gate of the sixth transistor TR6. In addition, the third word line WL13 may be connected to the gate of the third transistor TR3 and the gate of the seventh transistor TR7, and the fourth word line WL14 may be connected to the gate of the fourth transistor TR4 and the gate of the eighth transistor TR8. Likewise, the word lines WL21, WL22, WL23, and WL24 may be connected to the transistors TR9 to TR12 connected to the third bit line BL12 and the transistors TR13 to TR16 connected to the fourth bit line BL22.

The capacitors CS1 to CS16 included in each of the plurality of memory cells MC1 to MC16 may be connected to the transistors TR1 to TR16 included in each of the plurality of memory cells MC1 to MC16 in the direction of the first axis D1, which may be orthogonal to the direction of the third axis D3 in which the plurality of memory cells MC1 to MC16 are stacked. For example, the first capacitor CS1 to the fourth capacitor CS4 may be connected to the first transistor TR1 to the fourth transistor TR4 respectively along the first axis D1 direction, and the fifth capacitor CS5 to the eighth capacitor CS8 may be connected to the fifth transistor TR5 to the eighth transistor TR8 respectively along the first axis D1 direction. Additionally, the ninth capacitor CS9 to the twelfth capacitor CS12 may be connected to the ninth transistor TR9 to the twelfth transistor TR12 respectively along the first axis D1 direction, and the thirteenth capacitor CS13 to the sixteenth capacitor CS16 may be connected to the thirteenth transistor TR13 to the sixteenth transistor TR16 respectively along the first axis D1 direction.

When the first capacitor CS1 to the sixteenth capacitor CS16 are respectively connected to the first transistor TR1 to the sixteenth transistor TR16 along the first axis D1 direction, the chip space efficiency of the memory cell array 500 may be improved. As chip space efficiency improves, the number of memory cells MC1 to MC16 that may be integrated per area increases, which may improve the overall memory capacity.

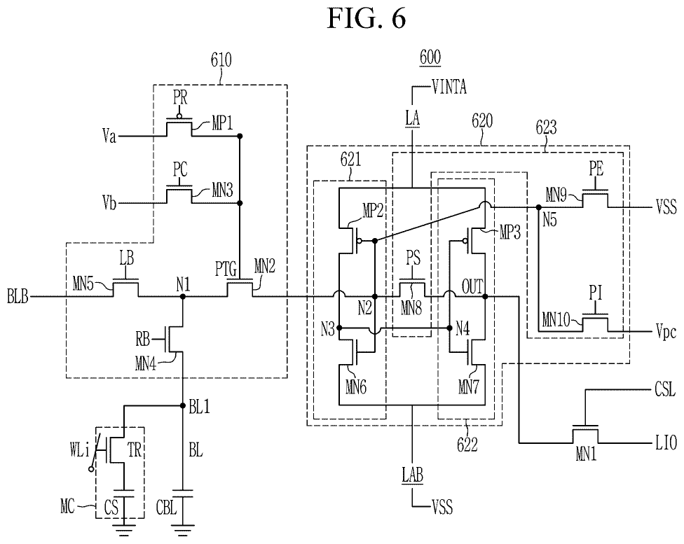

FIG. 6 is a circuit diagram illustrating a sense amplifier circuit 600 according to some embodiments.

Referring to FIG. 6, the sense amplifier circuit 600 may include a first circuit 610 and a second circuit 620. The first circuit 610 may be connected to a plurality of memory cells MC through a bit line BL and a complementary bit line BLB. Each of the plurality of memory cells MC may include a transistor TR and a capacitor CS.

The second circuit 620 may be electrically connected to a local input/output line LIO. The voltage of the output node OUT of the second circuit 620 may be transmitted to the local input/output line LIO through the local transistor MN1. A column select line CSL is connected to the gate of the local transistor MN1, and the operation of the local transistor MN1 may be determined based on the potential of the column select line CSL. For example, when the column select line CSL is at a logic high level voltage, the local transistor MN1 may be turned on, and when the column select line CSL is at a logic low level voltage, the local transistor MN1 may be turned off. Although the local transistor MN1 is shown to be an N-type transistor, the present disclosure is not limited thereto and, in some embodiments, it may be a P-type transistor.

The first circuit 610 may include a first control transistor MN2, a second control transistor MN3, a third control transistor MP1, a bit line transistor MN4, and a complementary bit line transistor MN5.

A source of the first control transistor MN2 may be connected to the first node N1, a drain of the first control transistor MN2 may be connected to the second node N2, and a control signal PTG may be applied to a gate of the first control transistor MN2. The control signal PTG may be a bias voltage Vb of the first control transistor MN2 or a supply voltage Va having a higher (i.e., greater) voltage level than the bias voltage Vb. The supply voltage Va may be VDD. The bias voltage Vb may be provided through the second control transistor MN3 turned on based on the control signal PC of the active level. The supply voltage Va may be provided through the third control transistor MP1 turned on based on the control signal PR of the active level. The bias voltage Vb and the supply voltage Va may be generated from a separate voltage generator (not shown).

A gate of the first control transistor MN2 may selectively receive a bias voltage Vb and a supply voltage Va. When the second control transistor MN3 is turned on and the third control transistor MP1 is turned off, a gate of the first control transistor MN2 may receive a bias voltage Vb. In addition, when the second control transistor MN3 is turned off and the third control transistor MP1 is turned on, the gate of the first control transistor MN2 may receive the supply voltage Va.

The bit line transistor MN4 and the complementary bit line transistor MN5 may be electrically connected to the first node N1. Specifically, a drain of the bit line transistor MN4 may be connected to the first node N1, and a drain of the complementary bit line transistor MN5 may be connected to the first node N1. The bit line BL and the complementary bit line BLB may receive charges accumulated in the first node N1 through the bit line transistor MN4 and the complementary bit line transistor MN5. The capacitance component CBL of the bit line BL may be connected in parallel with the memory cell MC with respect to the bit line node BL1.

The second circuit 620 may include a first inverter 621, a second inverter 622, and a precharge circuit 623.

The inverter (or the first inverter) 621 is connected between the high voltage line LA and the low voltage line LAB, and may provide the supply voltage VINTA of the high voltage line LA or the supply voltage VSS of the low voltage line LAB to the third node N3 according to the voltage of the second node N2. The inverter (or the second inverter) 622 is connected between the high voltage line LA and the low voltage line LAB, and may provide the supply voltage VINTA of the high voltage line LA or the supply voltage VSS of the low voltage line LAB to the output node OUT according to the voltage of the fourth node N4. In some embodiments, the inverters 621 and 622 may be a CMOS (complementary MOS) inverter. In this case, the inverter 621 may include a transistor MP2 between the high voltage line LA and the third node N3 and a transistor MN6 between the third node N3 and the low voltage line LAB, and the inverter 622 may include a transistor MP3 between the high voltage line LA and the output node OUT and a transistor MN7 between the output node OUT and the low voltage line LAB. The gate of the transistors MP2 and MN6 may be connected to the second node N2, which is a first input inverter terminal. The first inverter 621 includes the first input inverter terminal. In other words, the first inverter 621 may include an input terminal that is connected to the second node N2. The gate of the transistors MP3 and MN7 may be connected to the fourth node N4, which is a second input inverter terminal. The second inverter 622 includes the second input inverter terminal. In other words, the second inverter 622 may include an input terminal that is connected to the fourth node N4. The second inverter 622 may connected to the output node OUT. For example, the second inverter 622 may include an output terminal that is connected to the output node OUT.

The precharge circuit 623 may precharge the second node N2 to the first voltage VSS by transmitting a first voltage VSS to the second node N2 for a first period in response to a control signal PE, or may precharge the second node N2 to the second voltage Vpc by transmitting a second voltage Vpc to the second node N2 for a second period in response to the control signal PI. In some embodiments, the first voltage VSS may be a ground voltage or a negative voltage and the second voltage Vpc may be a voltage higher than the supply voltage VINTA of the high voltage line LA of the inverters 621 and 622. The second voltage Vpc may also be a voltage higher than the first voltage VSS. In some embodiments, the precharge circuit 623 may include transistors MN8, MN9, and MN10.

The first precharge transistor MN8 is connected between the second node N2 and the output node OUT, and may operate in response to a control signal PS. For example, a drain of the transistor MN8 may be connected to the second node N2, and a source of the first precharge transistor MN8 may be connected to the output node OUT. A gate of the first precharge transistor MN8 may receive a control signal PS.

The second precharge transistor MN9 may be connected between the fifth node N5 which is a contact point between the source of the second precharge transistor MN9 and the drain of the first precharge transistor MN8 and the ground terminal, and the third precharge transistor MN10 may be connected between the fifth node N5 and a line supplying a second voltage Vpc. The second precharge transistor MN9 may transmit the first voltage VSS to the second node N2 in response to the control signal PE, and the third precharge transistor MN10 may transmit the second voltage Vpc to the second node N2 in response to the control signal PI.

For example, in the second precharge transistor MN9, the drain may be connected to the fifth node N5, the source may be connected to the ground terminal, and the gate may receive the control signal PE. In addition, in the third precharge transistor MN10, the drain is connected to a line supplying the second voltage Vpc, the source is connected to the fifth node N5, and the gate may receive the control signal PI.

The first circuit 610 and the second circuit 620 may be connected to each other through a first control transistor MN2. Due to the potential difference between the first node N1 and the second node N2, a charge may be transferred between the first circuit 610 and the second circuit 620. In this case, the amount of charge transferred between the first circuit 610 and the second circuit 620 may be changed based on the voltage applied to the gate of the first control transistor MN2.

The first control transistor MN2 may have a channel length (L) and a channel width (W) greater than those of the other transistors MN1, MN3-MN10, and MP1-MP3. For example, the size of the first control transistor MN2 may be about twice as large as the channel length (L) and channel width (W) of the other transistors MN1, MN3 to MN10, and MP1 to MP3. When the first control transistor MN2 is connected to a node shared by the bit line BL and the complementary bit line BLB, the layout area of the first control transistor MN2 may be increased compared to the case where the first control transistor MN2 is connected to each of the bit line BL and the complementary bit line BLB.

Since the process variation of the transistor is inversely proportional to the channel length (L) and the channel width (W) of the transistor, the process variation of the transistor may decrease as the channel length (L) and the channel width (W) of the transistor increase. When the process variation of the transistor is reduced, the performance of the sense amplifier circuit 600 may be increased.

In some embodiments, the transistors MN1 to MN10 and MP1 to MP3 shown in FIG. 6 may be metal oxide semiconductor (MOS) transistors. In some embodiments, transistors MN1 to MN10 may be n-channel transistors, for example, NMOS transistors, and transistors MP1 to MP3 may be p-channel transistors, for example, PMOS transistors. The transistors MN1 to MN10 and MP1 to MP3 may have a source, a drain and a gate. The source and the drain may also be referred to as terminals, and the gate may also be referred to as a control terminal.

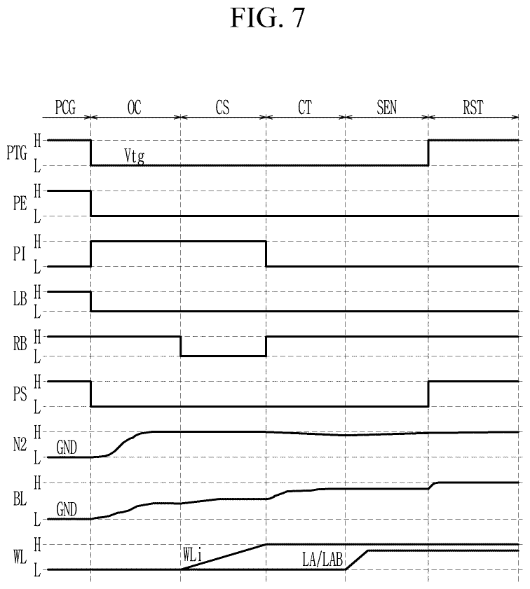

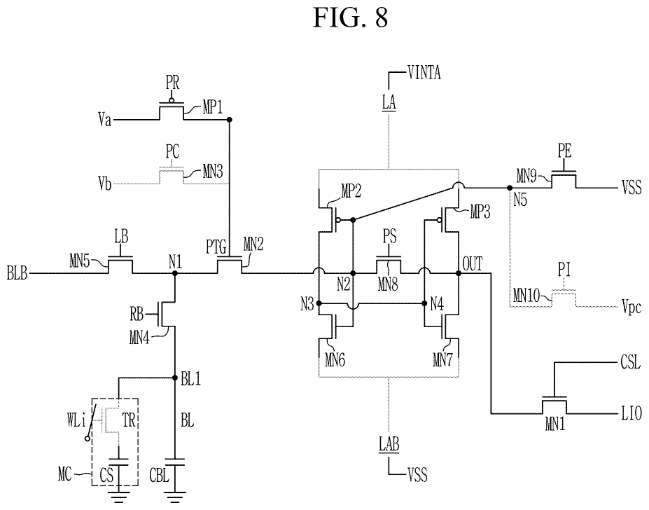

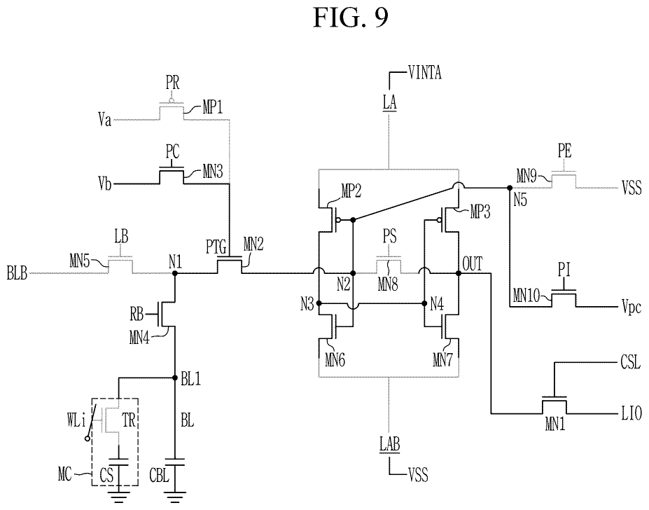

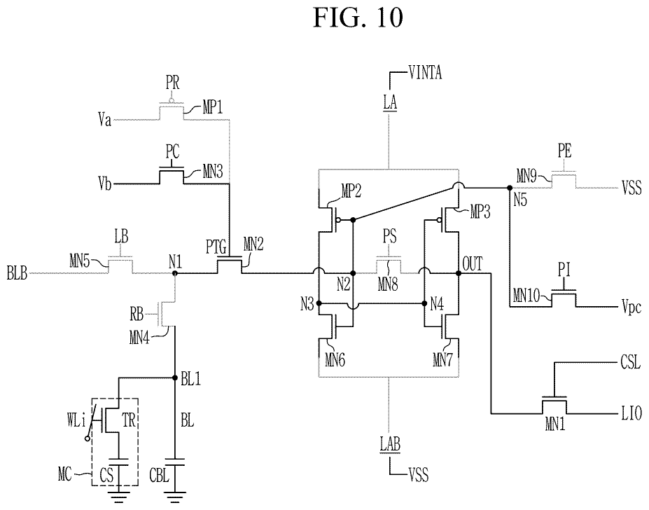

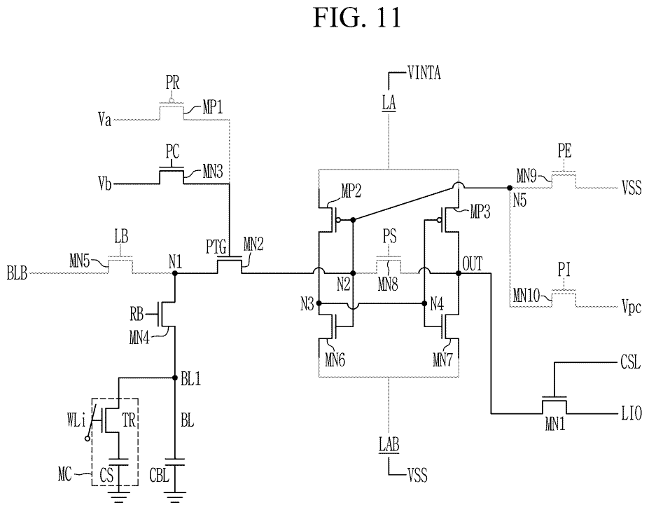

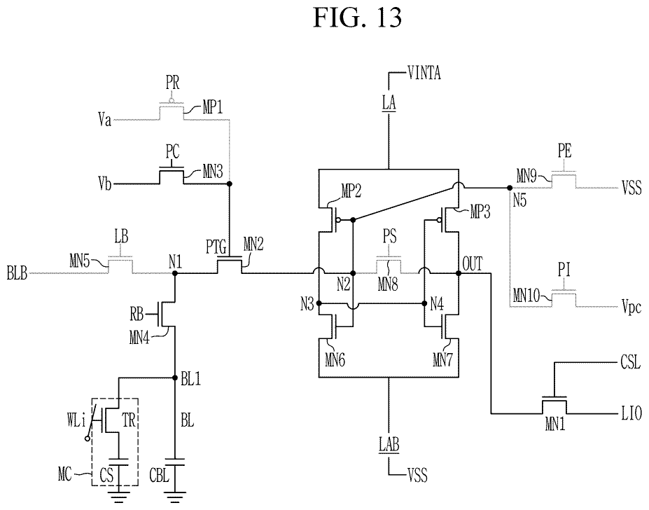

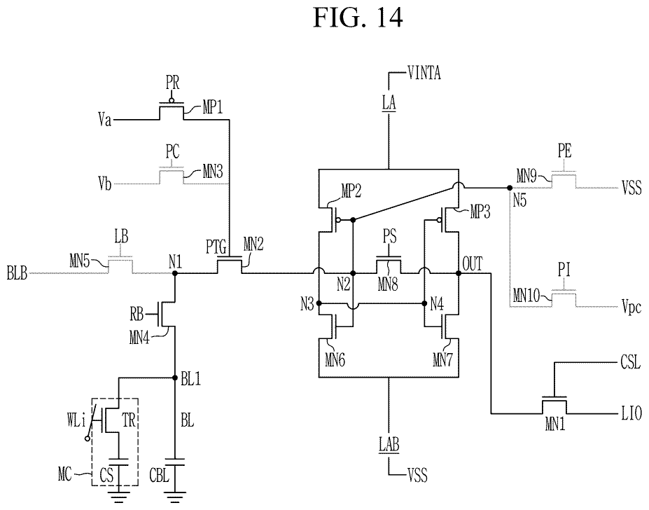

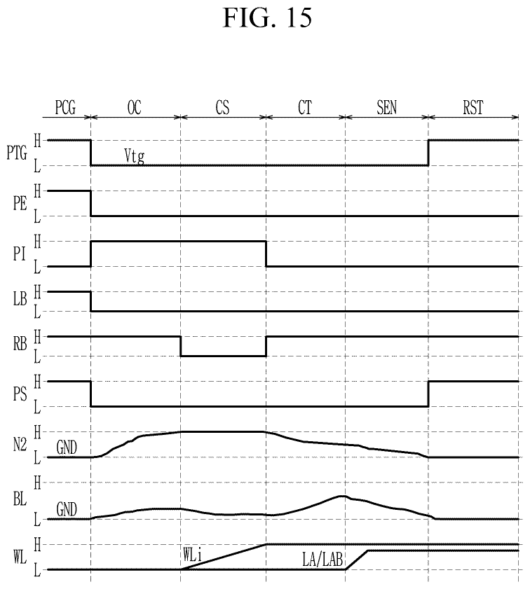

FIG. 7 and FIG. 15 are diagrams illustrating the operation timing of a sense amplifier circuit according to some embodiments. FIG. 8, FIG. 9, FIG. 10, FIG. 11, FIG. 13, and FIG. 14 are circuit diagrams illustrating the operation of the sense amplifier circuit according to the operation timing shown in FIG. 7. For example, as shown in FIG. 7, the sense amplifier circuit may sequentially perform a precharge operation PCG, an offset compensation operation OC, a charge sharing operation CS, a charge transfer operation CT, a sensing operation SEN, and a restoration operation RST. In FIG. 7, data of ‘1’ (i.e., data having a logic value of ‘1’) may be stored in the memory cell MC. In FIG. 15, data of ‘0’ (i.e., data having a logic value of ‘0’) may be stored in the memory cell MC.

Referring to FIGS. 7 and 8, the sense amplifier circuit may perform a precharge operation PCG to precharge the bit line BL, the complementary bit line BLB, and the second node N2 to the VSS.

When the bit line BL is precharged with the VSS, the sense amplifier circuit may more accurately sense data stored in the memory cell MC connected to the bit line BL than when the bit line BL is precharged with the intermediate voltage VBL, which is a value between the VDD and the VSS. For example, assuming that data of ‘0’ stored in the memory cell MC is stored and the bit line BL is precharged to the intermediate voltage VBL, the bit line BL may output a voltage less than or equal to the intermediate voltage VBL after the charge sharing operation CS. Assuming that data of ‘0 ’ stored in the memory cell MC is stored and the bit line BL is precharged to the VSS, the bit line BL may output the VSS after the charge sharing operation CS. The charge transfer operation CT, the sensing operation SEN, and the restoration operation RST may be performed based on a level of a voltage output from the bit line BL after the charge sharing operation CS. Accordingly, the sensing margin of the sense amplifier circuit may be improved by precharging the bit line BL to the VSS.

During the precharge operation PCG period, the second precharge transistor MN9 may be turned on based on a control signal PE of an active level (e.g., a high level), and the third precharge transistor MN10 may be turned off based on a control signal PI of an inactive level (e.g., a low level). Accordingly, the VSS may be precharged to the second node N2 through the second precharge transistor MN9. In other words, the precharge circuit 623 (see FIG. 6) may transfer the VSS to the second node N2 through the second precharge transistor MN9.

During the precharge operation PCG period, the third control transistor MP1 may be turned on based on a control signal PR of an active level (e.g., a low level), and the second control transistor MN3 may be turned off based on a control signal PC of an inactive level (e.g., a low level). The VDD (i.e., the supply voltage Va) is applied to the gate of the first control transistor MN2 as a control signal PTG, so that the first control transistor MN2 may be turned on. Accordingly, the VSS may be precharged to the first node N1 through the second precharge transistor MN9, the second node N2, and the first control transistor MN2.

During the precharge operation PCG period, the bit line transistor MN4 and the complementary bit line transistor MN5 may be turned on based on the control signals RB and LB of the active level (e.g., high level). Accordingly, the VSS may be precharged to the bit line BL and the complementary bit line BLB through the second precharge transistor MN9, the second node N2, and the first node N1. In other words, the VSS may be applied from the second node N2 to the bit line BL and the complementary bit line BLB. For example, the VSS may be transferred to the bit line BL, the complementary bit line BLB, the first node N1, and the second node N2 while the first control transistor MN2 is turned on. The capacitance component CBL present in the bit line BL may also be precharged to the VSS.

During the precharge operation PCG period, the first precharge transistor MN8 may be turned on based on a control signal PS of an active level (e.g., a high level). Accordingly, a VSS may be output from the output node OUT.

Referring to FIGS. 7 and 9, the sense amplifier circuit may perform an offset compensation operation OC. The sense amplifier circuit may perform an offset compensation operation OC that stores offset information of the first control transistor MN2 by connecting the bit line BL and the second node N2 through the first control transistor MN2.

During the offset compensation operation OC period, the second precharge transistor MN9 may be turned off based on a control signal PE of an inactive level (e.g., a low level), and the third precharge transistor MN10 may be turned on based on a control signal PI of an active level (e.g., a high level). Accordingly, the precharge voltage Vpc may be precharged to the second node N2 through the third precharge transistor MN10. In other words, the precharge circuit 623 (see FIG. 6) may transfer the precharge voltage Vpc to the second node N2 through the third precharge transistor MN10. At this time, the precharge voltage Vpc may be a voltage higher than the supply voltage VINTA of the high voltage line LA. The precharge voltage Vpc may also be a voltage higher than the first voltage VSS.

During the offset compensation operation OC period, the second control transistor MN3 may be turned on based on a control signal PC of an active level (e.g., a high level), and the third control transistor MP1 may be turned off based on a control signal PR of an inactive level (e.g., a high level). Accordingly, a bias voltage Vb may be applied to the gate of the first control transistor MN2 as a control signal PTG. The bias voltage Vb is a voltage between a high level voltage used as an active level and a low level voltage used as an inactive level, and may be a voltage higher than the threshold voltage Vth (i.e., the gate threshold voltage Vth) of the first control transistor MN2. However, the bias voltage Vb may be less than the VDD. In some embodiments, the bias voltage Vb may be set in consideration of charge transfer in a charge transfer operation CT to be described below.

The first control transistor MN2 to which the bias voltage Vb is applied may be in a weakly turned-on state. Accordingly, a current may flow from the second node N2 to which the precharge voltage Vpc is applied to the first node N1 to which the VSS is applied. However, if the difference between the voltage of the first node N1 connected to the source of the first control transistor MN2 and the voltage of the second node N2 connected to the drain of the first control transistor MN2 is smaller than the threshold voltage Vth of the first control transistor MN2, the first control transistor MN2 may be turned off. Accordingly, the first control transistor MN2 may be turned on until the difference between the voltage of the first node N1 and the voltage of the second node N2 reaches the threshold voltage Vth of the first control transistor MN2.

During the offset compensation operation OC, the complementary bit line transistor MN5 and the first precharge transistor MN8 may be turned off based on the control signals LB and PS of the inactive level (e.g., the low level). The bit line transistor MN4 may maintain a turned-on state based on the control signal RB of the active level (e.g., the high level). For example, the precharge voltage Vpc may be transferred to the second node N2 while the first precharge transistor MN8 is turned off.

Accordingly, the precharge voltage Vpc applied to the second node N2 may be applied to the bit line BL through the first control transistor MN2, the first node N1, and the bit line transistor MN4. In other words, the precharge voltage Vpc may be applied from the second node N2 to the bit line BL. However, the precharge voltage Vpc may be applied to the bit line BL until the difference between the voltage of the first node N1 and the voltage of the second node N2 reaches the threshold voltage Vth of the first control transistor MN2.

That is, the voltage of the bit line BL may be determined by the threshold voltage Vth of the first control transistor MN2. The voltage of the bit line BL may be determined as, for example, Vb-Vth. When compensation for the threshold voltage Vth of the first control transistor MN2 is not required in the bit line BL, the offset compensation operation OC may be omitted.

Referring to FIGS. 7 and 10, the sense amplifier circuit may perform a charge sharing operation CS for sharing charges between a bit line BL and a memory cell MC. In this case, the word line Wli connected to the gate of the memory cell MC may be activated.

During the charge sharing operation CS period, the bit line transistor MN4 may be turned off based on a control signal RB at an inactive level (e.g., a low level). Since the bit line transistor MN4 is turned off, the bit line BL may be electrically disconnected from the first node N1 and the second node N2. In other words, during the charge sharing operation CS period, the bit line BL may be electrically blocked from the first node N1 and the second N2 (e.g., by turning the bit line transistor MN4 off). For example, a current path between the bit line BL and the first and second nodes N1 and N2 may be blocked when the bit line transistor MN4 is turned off.

Since the transistor TR of the memory cell MC is turned on by the activation of the word line Wli connected to the gate of the memory cell MC, charge may be shared between the capacitor CS of the memory cell MC and the capacitance component CBL of the bit line. For example, a charge sharing operation may be performed between the capacitance component CBL of the bit line BL and the memory cell MC. Since data ‘1’ is stored in the memory cell MC, charges (e.g., electrons) may be transferred from the capacitance component CBL of the bit line to the capacitor CS. Accordingly, the voltage of the bit line BL may be increased.

Still referring to FIGS. 7 and 10, when the bit line BL is precharged to the VSS in the precharge operation PCG, the voltage of the bit line BL may increase more significantly compared to when the bit line BL is precharged to an intermediate voltage between the high level and the low level in the precharge operation PCG.

Meanwhile, the third precharge transistor MN10 may be maintained in a turn-on state based on a control signal PI of an active level (e.g., a high level). Accordingly, the precharge voltage Vpc may be continuously applied to the second node N2.

Additionally, since the bit line transistor MN4 and the complementary bit line transistor MN5 are turned off, current cannot flow through the first control transistor MN2, so the first control transistor MN2 may be turned off.

Referring to FIG. 7 and FIG. 11, the sense amplifier circuit may perform a charge transfer operation CT that transfers charge between the bit line BL and the second node N2 by connecting the bit line BL and the second node N2.

During the charge transfer operation CT period, the third precharge transistor MN10 may be turned off based on a control signal PI of an inactive level (e.g., a low level). Accordingly, the precharge voltage Vpc may not be applied to the second node N2. However, during the charge sharing operation CS period, since the precharge voltage Vpc has been applied to the second node N2, the voltage of the second node N2 may be greater than the voltage of the first node N1.

During the charge transfer operation CT period, the bit line transistor MN4 may be turned on based on a control signal RB of an active level (e.g., a high level).

Accordingly, the first node N1 may be electrically connected to the bit line BL.

During the charge transfer operation CT period, a bias voltage Vb may be applied to the gate of the first control transistor MN2. In some embodiments, the bias voltage Vb used in the charge transfer operation CT may be the same as the bias voltage Vb used in the offset compensation operation OC.

Then, by the voltage (Vb-VBL-Vth) obtained by subtracting the voltage of the bit line (BL) from the bias voltage Vb and the threshold voltage Vth of the first control transistor MN2, charge (e.g., electrons) may be transferred from the bit line BL to the second node N2, thereby decreasing the voltage of the second node N2. And, charge (e.g., electrons) may be transferred from the bit line BL to the second node N2, so that the voltage of the bit line BL may increase.

The voltage level of the second node N2 may be slightly reduced compared to the size of the previously precharged voltage Vpc. However, since the capacitance component of the second node N2 is larger than the capacitance component CBL of the bit line BL, the voltage decrease amount of the second node N2 may be lower than the voltage increase amount of the bit line BL.

Meanwhile, since the bit line BL is charged with a voltage determined by the threshold voltage Vth in the offset compensation operation OC, an offset by the threshold voltage Vth of the first control transistor MN2 may be offset in the charge transfer operation CT.

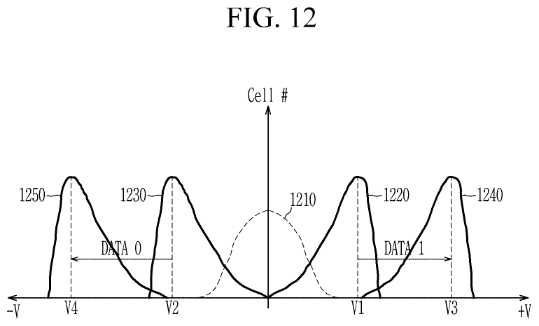

FIG. 12 is a graph illustrating the offset variation of the sense amplifier circuit, the variation of the charge sharing period, and the variation of the charge transfer period.

Referring to FIG. 12, a variation 1220 in a first-first charge sharing period CS is a graph illustrating a voltage of the second node N2 in a charge sharing period CS when data ‘1’ is stored in each of a plurality of memory cells. The variation 1230 in a first-second charge sharing CS period is a graph illustrating the voltage of the second node N2 in the charge sharing CS period when data ‘0’ is stored in each of the plurality of memory cells. In this case, the horizontal axis may represent the voltage V, and the vertical axis may represent the number of memory cells (Cell #).

The offset variation 1210 of the sense amplifier circuit may partially overlap the variation 1220 in the first-first charge sharing CS period and the variation 1230 in the first-second charge sharing CS period. For example, based on the same voltage, there may be a region where the offset variation 1210 of the sense amplifier circuit exceeds the variation 1220 of the first-first charge sharing CS period or the variation 1230 of the first-second charge sharing CS period, which is a partially overlapping region.

During a sensing operation period, errors may occur when the sense amplifier circuit senses a plurality of memory cells corresponding to overlapping regions. For example, a sense amplifier circuit may sense a memory cell storing data ‘1’ as data ‘0’. Conversely, a sense amplifier circuit may sense a memory cell storing data ‘0’ as data ‘1’. This is because the voltage difference between the output voltage V1 of the second node N2 in the variation 1220 of the first-first charge sharing CS period and the output voltage V2 of the second node N2 in the variation 1230 of the first-second charge sharing CS period is significantly small.

Still referring to FIG. 12, the variation 1240 of the second-first charge transfer CT period is a graph illustrating the voltage of the second node N2 in the charge transfer CT period when data ‘1’ is stored in each of a plurality of memory cells. The variation 1250 of the second-second charge transfer CT period is a graph illustrating the voltage of the second node N2 in the charge transfer CT period when data ‘0’ is stored in each of a plurality of memory cells. In this case, the horizontal axis may represent the voltage V, and the vertical axis may represent the number of memory cells (Cell #).

The offset variation 1210 of the sense amplifier circuit may not overlap with the variation 1240 of the second-first charge transfer CT period and the variation 1250 of the second-second charge transfer CT period. The voltage difference between the output voltage V3 of the second node N2 in the variation 1240 of the second-first charge transfer CT period and the output voltage V4 of the second node N2 in the variation 1250 of the second-second charge transfer CT period may be greater than the voltage difference between the output voltage V1 of the second node N2 in the variation 1220 of the first-first charge sharing CS period and the output voltage V2 of the second node N2 in the variation 1230 of the first-second charge sharing CS period.

Referring to FIG. 7 and FIG. 12, when a bit line BL precharged to a VSS during a precharge operation PCG period shares charge with a memory cell storing data ‘1’ during a charge sharing operation CS period, the voltage of the bit line BL may increase. Additionally, a precharge voltage Vpc may be applied to the second node N2 during the charge sharing operation CS period. At this time, the precharge voltage Vpc of the second node N2 may be higher than the voltage of the bit line BL.

During the charge transfer operation CT period, charges (e.g., electrons) are transferred from the bit line BL to the second node N2 to which the precharge voltage Vpc is applied, so that the voltage of the second node N2 may decrease. However, the voltage drop of the second node N2 during the charge transfer operation CT period may be reduced in proportion to the voltage increase in the bit line BL during the charge sharing operation CS. During the precharge operation PCG period, the bit line BL which is precharged to the VSS receives voltage from the memory cell during the charge sharing operation CS period, so that the voltage of the bit line BL may increase significantly. Accordingly, the voltage drop of the second node N2 during the charge transfer operation CT period may be reduced.

Referring to FIG. 12 and FIG. 15, when a bit line BL precharged to a VSS during a precharge operation PCG period shares charge with a memory cell storing data ‘0’ during a charge sharing operation CS period, the voltage of the bit line BL may be close to the VSS. In contrast, a precharge voltage Vpc may be applied to the second node N2 during the charge sharing operation CS period.

During the charge transfer CT operation period, charges (e.g., electrons) are transferred from a bit line BL close to a VSS to a second node N2 to which a precharge voltage Vpc is applied, so that the voltage of the second node N2 may decrease. Accordingly, the output voltage V4 of the second node N2 in the variation 1250 of the second-second charge transfer CT period may be lower than the output voltage V2 of the second node N2 in the variation 1230 of the first-second charge sharing CS period.

The output voltage V4 of the second node N2 may be lower than the output voltage V2, and the output voltage V3 of the second node N2 may be higher than the output voltage V1. During the charge transfer operation CT period, the voltage difference between the output voltage V3 and the output voltage V4 of the second node N2 may be higher than the voltage difference between the output voltage V1 and the output voltage V2 of the second node N2 during the charge sharing operation CS period.

Accordingly, the offset variation 1210 of the sense amplifier circuit may not overlap with the variation 1240 of the second-first charge transfer CT period and the variation 1250 of the second-second charge transfer CT period. The possibility of errors occurring when a sense amplifier circuit senses a plurality of memory cells over a charge transfer operation CT period may thus be reduced.

Referring to FIG. 7 and FIG. 13, the sense amplifier circuit may perform a sensing operation SEN that outputs the voltage of the output node OUT.

During the sensing operation SEN period, the transistor MN6 may be turned on and the transistor MP2 may be turned off by the voltage of the second node N2. Through the turned-on transistor MN6, the voltage of the third node N3 and the fourth node N4 may be reduced to the VSS of the low voltage line LAB. For example, during the sensing operation SEN period, the high voltage line LA that transmits the supply voltage VINTA and the low voltage line LAB that transmits the first voltage VSS may be turned on.

During the sensing operation SEN period, the transistor MN7 may be turned off and the transistor MP3 may be turned on by the voltage of the fourth node N4. Through the turned-on transistor MP3, the voltage at the output node OUT may be increased to the supply voltage VINTA of the high voltage line LA. The sense amplifier circuit may sense that high level (i.e., ‘1’) data is stored in the memory cell MC. For example, the data of the memory cell MC sensed by the sense amplifier circuit (e.g., high level or low level) may be based on a voltage at the second node N2.

Referring to FIG. 7 and FIG. 14, the sense amplifier circuit may perform a restoration operation RST to restore the voltage of the memory cell MC.

During the restoration operation RST period, the second control transistor MN3 may be turned off based on a control signal PC of an inactive level (e.g., a low level), and the third control transistor MP1 may be turned on based on a control signal PR of an active level (e.g., a low level). As a control signal PTG, a supply voltage Va may be applied to the gate of the first control transistor MN2. The first control transistor MN2 that is supplied with the supply voltage Va may be fully turned on.

During the restoration operation RST period, the first precharge transistor MN8 may be turned on based on a control signal PS of an active level (e.g., a high level). And, charge (e.g., electrons) may be transferred from the capacitor CS of the memory cell MC to the output node OUT through the bit line transistor MN4, the first node N1, the first control transistor MN2, the second node N2, and the first precharge transistor MN8. Accordingly, the voltage of the output node OUT decreases, and data ‘1’ can be restored to the memory cell MC.

Referring to FIG. 15, the control signals PTG, PE, PI, LB, RB, PS, and WL may have the same timing as the control signals PTG, PE, PI, LB, RB, PS, and WL described with reference to FIG. 7. Therefore, the precharge operation PCG and the offset compensation operation OC may be performed as described with reference to FIGS. 7 to 9.

During the charge sharing operation CS period, since data of ‘0’ is stored in the capacitor of the memory cell MC, the voltage of the bit line BL may decrease due to charge sharing between the memory cell MC and the bit line BL. In other words, since data ‘0’ is stored in the memory cell MC, charges (e.g., electrons) may be transferred from the capacitor CS to the capacitance component CBL of the bit line.

During a charge transfer operation CT period, charges (e.g., electrons) may be transferred from the bit line BL to the second node N2, causing the voltage of the second node N2 to decrease. In this case, since the voltage of the bit line BL is close to the ground voltage, the voltage of the second node N2 may be significantly reduced compared to that shown in FIG. 7. And, charge (e.g., electrons) may be transferred from the bit line BL to the second node N2, so that the voltage of the bit line BL may increase.

However, since the capacitance component of the second node N2 is larger than the capacitance component CBL of the bit line BL, the voltage decrease amount of the second node N2 may be lower than the voltage increase amount of the bit line BL.

Referring to FIG. 13 and FIG. 15, during the sensing operation SEN period, the transistor MN6 may be turned off and the transistor MP2 may be turned on by the voltage of the second node N2. Through the turned-on transistor MP2, the voltage of the third node N3 and the fourth node N4 may increase to the supply voltage VINTA of the high voltage line LA.

During the Sensing Operation Sen Period, the Transistor Mn7 May Be Turned on and the transistor MP3 may be turned off by the voltage of the fourth node N4. Through the turned-on transistor MN7, the voltage at the output node OUT may be reduced to the supply voltage VSS of the low voltage line LAB. The sense amplifier circuit may sense that low level (i.e., ‘0’) data is stored in the memory cell MC. For example, the data of the memory cell MC sensed by the sense amplifier circuit (e.g., high level or low level) may be based on a voltage at the second node N2.

Since the supply voltage difference dVBL of the second node N2 becomes relatively large due to the charge sharing operation CS and/or the charge transfer operation CT, accurate sensing may be performed. At this time, the supply voltage difference dVBL may be amplified by the ratio of capacitance component CBL of the bit line BL/capacitance component CBL of the second node N2.

Referring to FIG. 14 and FIG. 15, during the restoration operation RST period, the first precharge transistor MN8 may be turned on based on a control signal PS of an active level (e.g., a high level). And, charge (e.g., electrons) can be transferred from the output node OUT to the capacitor CS of the memory cell MC through the bit line transistor MN4, the first node N1, the first control transistor MN2, the second node N2, and the first precharge transistor MN8. Accordingly, the voltage of the output node OUT may increase, and data ‘0’ may be restored to the memory cell MC.

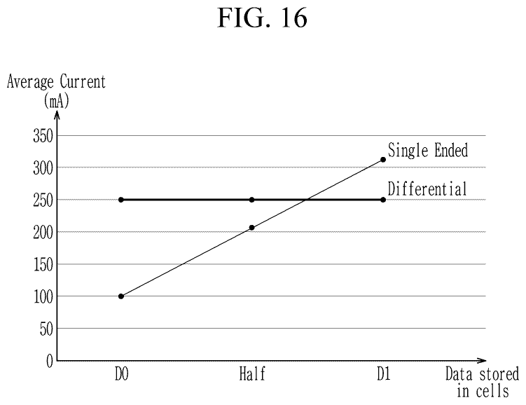

FIG. 16 is a graph illustrating the amount of current generated in a sense amplifier circuit according to some embodiments.

Referring to FIG. 16, a differential sense amplifier circuit may amplify the voltage difference between a bit line BL and a complementary bit line BLB during the process of reading data from a memory cell. A differential sense amplifier circuit may increase one voltage and decrease the other voltage to amplify the voltage difference between a bit line BL and a complementary bit line BLB.

For example, if a differential sense amplifier circuit increases the voltage of the bit line BL, the voltage of the complementary bit line BLB may be lowered, and if the voltage of the complementary bit line BLB is increased, the voltage of the bit line BL may be lowered. Accordingly, regardless of the type of data stored in the memory cell MC (‘0’ or ‘1’), the current generated while the sense amplifier circuit reads the data of the memory cell may be about 250 milliamps (mA).

The sense amplifier circuit according to some embodiments is a single-ended method (e.g., a single-ended circuit) in which each of the bit line BL and the complementary bit line BLB is connected to the first node N1, and the single-ended sense amplifier circuit may operate differently depending on the type of data stored in the memory cell MC (‘0’ or ‘1’).

For example, a single-ended sense amplifier circuit does not need to increase the voltage of the bit line BL if the data stored in each of the plurality of memory cells connected to the bit line BL are all ‘0’. In this case, the current generated while the sense amplifier circuit reads the data of the memory cell may be about 100 mA.

In addition, when data ‘0’ is stored in half of the memory cells among a plurality of memory cells connected to a bit line BL and data ‘1’ is stored in the remaining memory cells, only the voltage of the bit line BL where data ‘1’ is stored may be increased. In this case, the current generated while the sense amplifier circuit reads data of a memory cell may be about 200 mA.

Accordingly, the single-ended type sense amplifier circuit may be driven with lower power than a differential type sense amplifier circuit.

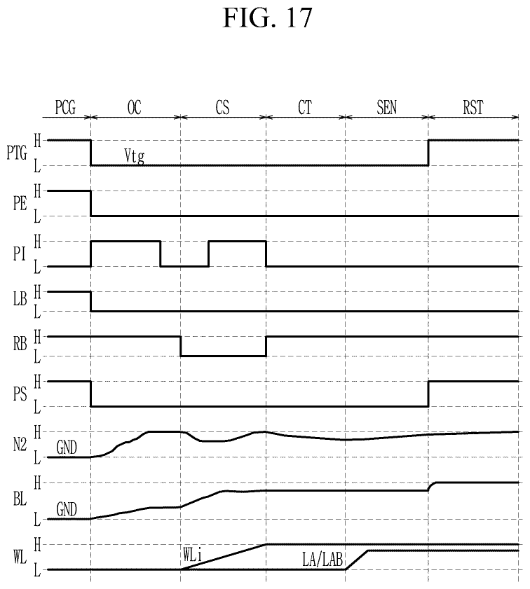

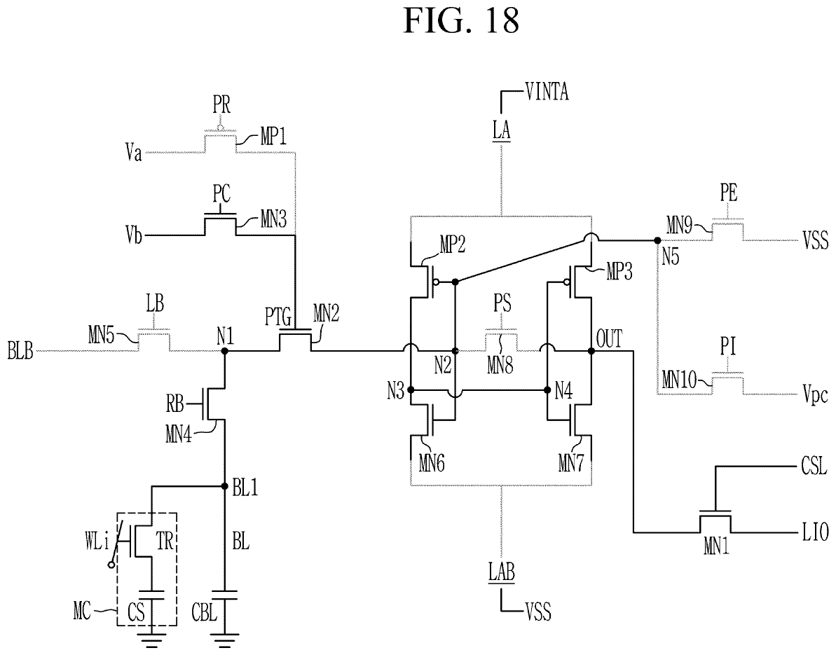

FIG. 17 is a diagram illustrating an operation timing of a sense amplifier circuit according to some further embodiments, and FIG. 18 is a circuit diagram illustrating a third precharge transistor turned off during an offset compensation operation OC according to some further embodiments.

Referring to FIG. 17, the control signals PTG, PE, LB, RB, PS and WL may have the same timing as the control signals PTG, PE, LB, RB, PS and WL described with reference to FIG. 7. Therefore, the precharge operation PCG may be performed as described with reference to FIGS. 7 and 8. In FIG. 17, data of ‘1’ may be stored in the memory cell MC.

Referring to FIG. 17 and FIG. 18, the sense amplifier circuit may fully turn off the first control transistor MN2 during the offset compensation operation OC process to reduce the leakage current generated in the first control transistor MN2.

Referring to FIG. 9 and FIG. 17, during the offset compensation operation OC period, the third precharge transistor MN10 may be turned on based on a control signal PI of an active level (e.g., a high level). Accordingly, the precharge voltage Vpc is applied to the second node N2, so that the voltage of the second node N2 may be greater than the voltage of the first node N1. A VSS is applied to the first node N1 in the precharge operation PCG, and a voltage difference between the second node N2 and the first node N1 may exceed the threshold voltage Vth of the first control transistor MN2.

Referring to FIG. 17 and FIG. 18, during the offset compensation operation OC period, the control signal PI of the active level (e.g., the high level) may transition to the control signal PI of the inactive level (e.g., the low level). The third precharge transistor MN10 may be turned off, and the precharge voltage Vpc may no longer be applied to the second node N2. When the voltage applied to the second node N2 decreases to the voltage applied to the first node N1, a voltage difference between the voltage of the first node N1 that is the source terminal of the first control transistor MN2 and the voltage of the second node N2 that is the drain terminal of the first control transistor MN2 may approach zero. In addition, the difference between the voltage applied to the source terminal of the first control transistor MN2 and the voltage applied to the drain terminal of the first control transistor MN2 may be smaller than the threshold voltage Vth of the first control transistor MN2. Accordingly, the first control transistor MN2 may be turned off.

In the turned-off state of the first control transistor MN2, a conductive channel is not formed as compared with the turned-on state of the first control transistor MN2, and thus a main path through which current flows may be blocked. Accordingly, leakage current generated in the first control transistor MN2 may be reduced. In addition, since the leakage current generated in the first control transistor MN2 is reduced, the voltage variability of the bit line BL electrically connected to the first node N1 may also be reduced.

In the charge sharing operation CS period, since data of ‘1’ is stored in the capacitor of the memory cell MC, the voltage of the bit line BL may increase due to charge sharing between the memory cell MC and the bit line BL. As shown in FIG. 10 and FIG. 17, in the charge sharing operation CS period, the precharge voltage Vpc is applied again to the second node N2 to prepare for the charge transfer operation CT of the sense amplifier circuit. For example, in the charge sharing operation CS period, the third precharge transistor MN10 may be turned on.

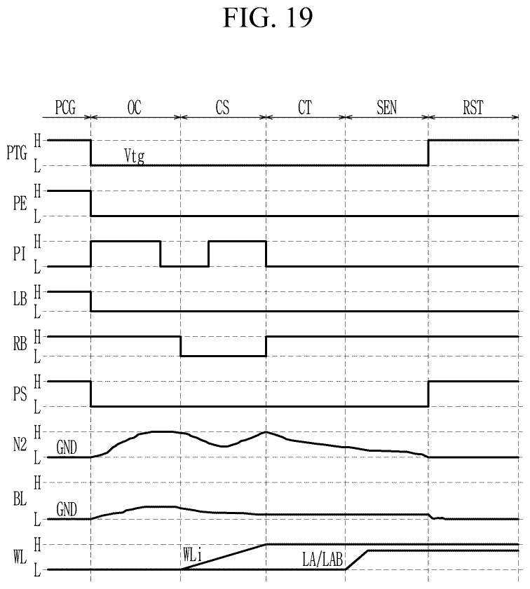

FIG. 19 is a diagram illustrating the operation timing of a sense amplifier circuit according to some further embodiments.

Referring to FIG. 19, the control signals PTG, PE, PI, LB, RB, PS, and WL may have the same timing as the control signals PTG, PE, PI, LB, RB, PS, and WL described with reference to FIG. 17. Therefore, the precharge operation PCG and the offset compensation operation OC may be performed as described with reference to FIGS. 17 and 18. In FIG. 19, data of ‘0’ may be stored in the memory cell MC.

The first control transistor MN2 may be turned off in the offset compensation operation OC period (see FIG. 18), and may be turned on again in the charge sharing operation CS period (see FIG. 10). In the turned-off state of the first control transistor MN2, a conductive channel is not formed as compared with the turned-on state of the first control transistor MN2, and thus a main path through which current flows may be blocked. Accordingly, the leakage current generated in the first control transistor MN2 may be reduced in the period in which the first control transistor MN2 is turned off.

In the charge sharing operation CS period, since data of ‘0’ is stored in the capacitor of the memory cell MC, the voltage of the bit line BL may be reduced by charge sharing between the memory cell MC and the bit line BL. In the charge sharing operation CS period, the precharge voltage Vpc is applied to the second node N2 again to prepare for the charge transfer operation CT of the sense amplifier circuit.

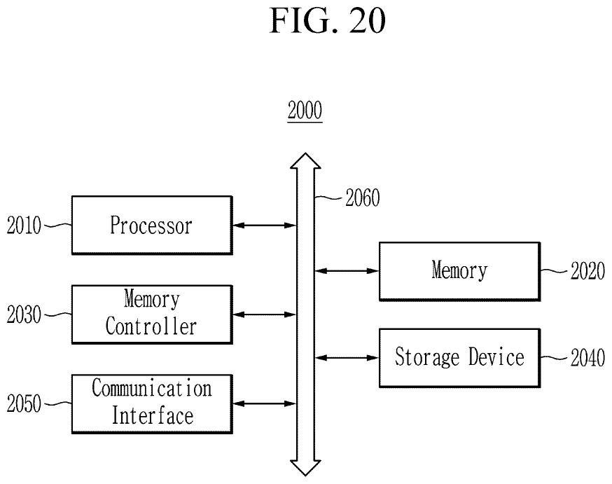

FIG. 20 is a block diagram illustrating a computer device according to some embodiments.

Referring to FIG. 20, the computing device 2000 includes a processor 2010, a memory 2020, a memory controller 2030, a storage device 2040, a communication interface 2050, and a bus 2060. Computing device 2000 may further include other general-purpose components.

The processor 2010 controls the overall operation of each component of the computing device 2000. The processor 2010 may be implemented as at least one of various processing units such as a central processing unit CPU, an application processor AP, and a graphic processing unit GPU.

The memory 2020 stores various data and commands. The memory 2020 may be implemented as the memory device described with reference to FIGS. 1 and 4. The memory controller 2030 controls transmission of data or commands to and from the memory 2020. In some embodiments, the memory controller 2030 may be provided as a chip separate from the processor 2010. In some embodiments, the memory controller 2030 may be provided as an internal configuration of the processor 2010.

The storage device 2040 non-temporarily stores programs and data. In some embodiments, the storage device 2040 may be implemented as a non-volatile memory device. The communication interface 2050 supports wired and wireless Internet communication of the computing device 2000. Additionally, the communication interface 2050 may support various communication methods other than Internet communication. The bus 2060 provides a communication function between components of the computing device 2000. The bus 2060 may include at least one type of bus according to a communication protocol between components.

Although example embodiments of the present disclosure have been described above with reference to the accompanying drawings, the present disclosure is not limited to the above-described embodiments. It will be understood that various modifications may be made to the present disclosure without departing from the scope of the appended claims. Therefore, it should be appreciated that the embodiments as described above are not restrictive but illustrative in all respects.

What is claimed is:

1. A sense amplifier circuit comprising:
a first bit line;
a bit line transistor electrically connected between the first bit line and a first node;
a first control transistor electrically connected between the first node and a second node;
a first inverter including an input terminal electrically connected to the second node;
a second inverter electrically connected to an output node; and
a precharge circuit electrically connected to the second node and configured to transfer a first voltage to the second node during a first time period and to transfer a second voltage greater than the first voltage to the second node during a second time period.

2. The sense amplifier circuit of claim 1, further comprising:
a complementary bit line pair comprising the first bit line and a second bit line; and
a complementary bit line transistor electrically connected between the second bit line and the first node.

3. The sense amplifier circuit of claim 2, wherein the complementary bit line transistor and the bit line transistor are configured to selectively turn on.

4. The sense amplifier circuit of claim 2, wherein the precharge circuit comprises:
a first precharge transistor electrically connected between the second node and the output node;
a second precharge transistor including a first terminal electrically connected to the second node and a second terminal configured to receive the first voltage; and
a third precharge transistor including a first terminal electrically connected to the second node and a second terminal configured to receive the second voltage.

5. The sense amplifier circuit of claim 4, wherein:
the second node is configured to selectively receive the first voltage and the second voltage, and
the first voltage is a first supply voltage, and the second voltage is a precharge voltage.

6. The sense amplifier circuit of claim 5, further comprising:
a second control transistor including a first terminal electrically connected to a gate of the first control transistor and a second terminal configured to receive a bias voltage; and
a third control transistor including a first terminal electrically connected to the gate of the first control transistor and a second terminal configured to receive a second supply voltage.

7. The sense amplifier circuit of claim 6, wherein:
the bias voltage is greater than a gate threshold voltage of the first control transistor, and
the second supply voltage is greater than the bias voltage.

8. The sense amplifier circuit of claim 7, wherein the gate of the first control transistor is configured to selectively receive the bias voltage and the second supply voltage.

9. The sense amplifier circuit of claim 8, wherein:
the first inverter is electrically connected between a first voltage line configured to transmit a third voltage and a second voltage line configured to transmit the first voltage,
the second inverter is electrically connected between the first voltage line and the second voltage line, and
the third voltage is greater than the first voltage and less than the second voltage.

10. The sense amplifier circuit of claim 9, wherein:
during the first time period, the first voltage is applied to the second node and the second supply voltage is applied to the gate of the first control transistor, so that the first voltage is applied from the second node to the first bit line,
during the second time period, which is after the first time period, the second voltage is applied to the second node and the bias voltage is applied to the gate of the first control transistor, so that the second voltage is applied from the second node to the first bit line,
during a third time period after the second time period, the bit line transistor is configured to turn off,
during a fourth time period after the third time period, the bit line transistor is configured to turn on and the third precharge transistor is configured to turn off,
during a fifth time period after the fourth time period, the first voltage line that transmits the third voltage and the second voltage line that transmits the first voltage are configured to turn on, and
during a sixth time period after the fifth time period, the second supply voltage is applied to the gate of the first control transistor, and the first precharge transistor is configured to turn on.

11. The sense amplifier circuit of claim 10, wherein during the second time period, the complementary bit line transistor and the first precharge transistor are configured to turn off, and the bit line transistor is configured to be on.

12. The sense amplifier circuit of claim 10, wherein:
during the second time period, the third precharge transistor is configured to turn off, and
during the third time period, the third precharge transistor is configured to turn on.

13. A sense amplifier circuit comprising:
a memory cell;
a bit line electrically connected to the memory cell;
a first node;
a second node;
a bit line transistor electrically connected between the bit line and the first node;
a first control transistor electrically connected between the first node and the second node;
a first inverter including an input terminal electrically connected to the second node;
a second inverter including an output terminal electrically connected to an output node; and
a first precharge transistor electrically connected between the second node and the output node,
wherein the sense amplifier circuit is configured to:
during a first time period, transfer a first voltage to the bit line, the first node, and the second node while the first control transistor is turned on,
during a second time period after the first time period, transfer a second voltage greater than the first voltage to the second node while the first precharge transistor is turned off,
during a third time period after the second time period, perform a charge sharing operation between a capacitance component of the bit line and the memory cell, wherein the bit line transistor is configured to turn off during the third time period, and
during a fourth time period after the third time period, transfer a charge from the bit line to the second node, wherein the bit line transistor is configured to turn on during the fourth time period,
wherein during a fifth time period after the fourth time period, a first voltage line and a second voltage line electrically connected to each of the first inverter and the second inverter are configured to turn on, and
wherein during a sixth time period after the fifth time period, the first control transistor is configured to be on and the first precharge transistor is configured to turn on.

14. The sense amplifier circuit of claim 13, wherein during the second time period, the first control transistor is configured to be on and the bit line transistor is configured to be on.

15. The sense amplifier circuit of claim 13, wherein during the third time period:
the memory cell is configured to store data having a logic value of 1, and
the charge sharing operation comprises transferring a charge from the capacitance component of the bit line to the memory cell.

16. The sense amplifier circuit of claim 13, wherein during the third time period:
the memory cell is configured to store data having a logic value of 0, and
the charge sharing operation comprises transferring a charge from the memory cell to the capacitance component of the bit line.

17. The sense amplifier circuit of claim 13, wherein a channel length and a channel width of the first control transistor are greater than a channel length and a channel width of the bit line transistor, respectively.

18. A sensing method of a memory device comprising:
precharging a bit line and a first node electrically connected to the bit line with a first voltage;
storing offset information of a transistor electrically connected between the first node and a second node;
precharging the second node with a second voltage greater than the first voltage and sharing a charge between a memory cell and the bit line;
transferring the charge from the bit line to the second node; and
sensing data of the memory cell based on a voltage at the second node.

19. The sensing method of claim 18, wherein the first voltage is a ground voltage.

20. The sensing method of claim 18, wherein sharing the charge between the memory cell and the bit line comprises electrically blocking the bit line from the first node.
